(19) United States
(12) Patent Application Publication
(10) Pub. No.: US 2025/0245547 A1
(43) Pub. Date: Jul. 31, 2025

(54) HUMAN-CENTRIC EVALUATION OF ARCHITECTURAL SPACES

(71) Applicant: AUTODESK, INC., San Francisco, CA (US)

(72) Inventors: Bon Adriel ASENIERO, Toronto (CA); Rhys GOLDSTEIN, Toronto (CA); Michael LEE, Toronto (CA); Nastaran SHAHMANSOURI, San Francisco, CA (US); Yi WANG, Richmond, CA (US)

(21) Appl. No.: 18/423,153

(22) Filed: Jan. 25, 2024

(51) Int. Cl. G06N 20/00

(52) U.S. Cl. CPC G06N 20/00

(57) ABSTRACT

One embodiment of the present invention sets forth a technique for evaluating architectural spaces. This technique includes receiving a 2D input image of an architectural space and generating one or more prompts. Each prompt includes one of a plurality of human-centric criteria. The plurality of human-centric criteria may include terms such as “social,” “isolating,” “tranquil,” “distracting,” “inspirational,” or “boring.” The technique also includes generating, via a trained machine learning model, an alignment score associated with each of the prompts and the 2D input image, wherein the alignment score indicates a degree of alignment between the prompt and the 2D input image. The technique further includes storing the 2D input image and generated alignment scores for later retrieval and/or presentation to a user.

### BACKGROUND

### Field of the Various Embodiments

Embodiments of the present disclosure relate generally to machine learning and computer vision and, more specifically, to machine learning techniques for evaluating architectural spaces.

### Description of the Related Art

Users, such as architects, building planners, or interior designers, often evaluate an architectural space based on one or more human-centric evaluation criteria. For example, an architect may consider whether a proposed space for an entryway or a lobby in a building is “inspirational” or “boring.” A building planner may wish to choose a “social” space for a dining facility rather than a space that the building planner considers to be “isolating.” For an office or other working space, a “tranquil” environment may be more suitable than a “distracting” environment. Such human-centric evaluations of architectural spaces may be useful when assigning existing spaces in a building to various functions or purposes. Human-centric evaluations may also be valuable when planning renovations or rehabilitations of existing spaces so that the spaces may best satisfy specific criteria related to their intended future use. Prior to construction, human-centric evaluations of 2D renderings based on proposed floor plans may provide insight into the suitability of various spaces in view of their specified purposes.

Existing machine learning techniques for human-centric evaluation of architectural spaces rely on training data drawn from human evaluation of architectural spaces, based on direct observation of the spaces in an existing building or analysis of floor plans and other architectural drawings. One drawback of the existing techniques is that there is a lack of sufficiently large training data sets that include human evaluations of architectural spaces. Human evaluation is necessarily subjective, and depends on the evaluator's expertise, experience, and personal preferences. This subjectivity may result in inconsistent or conflicting evaluations of one or more spaces by multiple evaluators, or even inconsistent evaluations of a single space by a single evaluator over time. As a result, training data collected in sufficiently large quantities from multiple evaluators, or over a period of time, may not be internally consistent. This inconsistency complicates training a machine learning model to accurately and consistently perform human-centric evaluation of architectural spaces.

As the foregoing illustrates, what is needed in the art are more effective techniques for performing human-centric evaluation of architectural spaces.

### SUMMARY

In one embodiment of the present invention, a computer-implemented method for evaluating an architectural space includes generating a textual prompt, wherein the textual prompt includes a human-centric evaluation criterion and generating, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion. The method also includes assigning the human-centric evaluation criterion and the alignment score to the 2D input image, and displaying, via a graphical user interface, one or more of the 2D input image, the human-centric evaluation criterion, and the alignment score.

One technical advantage of the disclosed technique relative to the prior art is that the disclosed techniques provide consistent, quantifiable, repeatable evaluations of architectural spaces based on human-centric criteria. The disclosed techniques refine a pre-trained model by iteratively training the model on a relatively smaller quantity of image-text pairs representing human evaluations of architectural spaces. The disclosed techniques may be applied to two-dimensional (2D) photographs of architectural spaces, 2D renderings of architectural spaces, or 2D still images representing individual frames from a 3D video walkthrough of one or more architectural spaces. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a computing device configured to implement one or more aspects of various embodiments.

FIG. 2 is a more detailed illustration of training engine of FIG. 1, according to some embodiments.

FIG. 3 is a more detailed illustration of evaluation engine of FIG. 1, according to some embodiments.

FIG. 4 illustrates an example evaluation display, according to various embodiments.

FIG. 5 is a flow diagram of method steps for training a machine learning model to generate alignment scores for a 2D input image based on one or more human-centric evaluation criteria, according to various embodiments.

FIG. 6 is a flow diagram of method steps for evaluating an architectural space, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

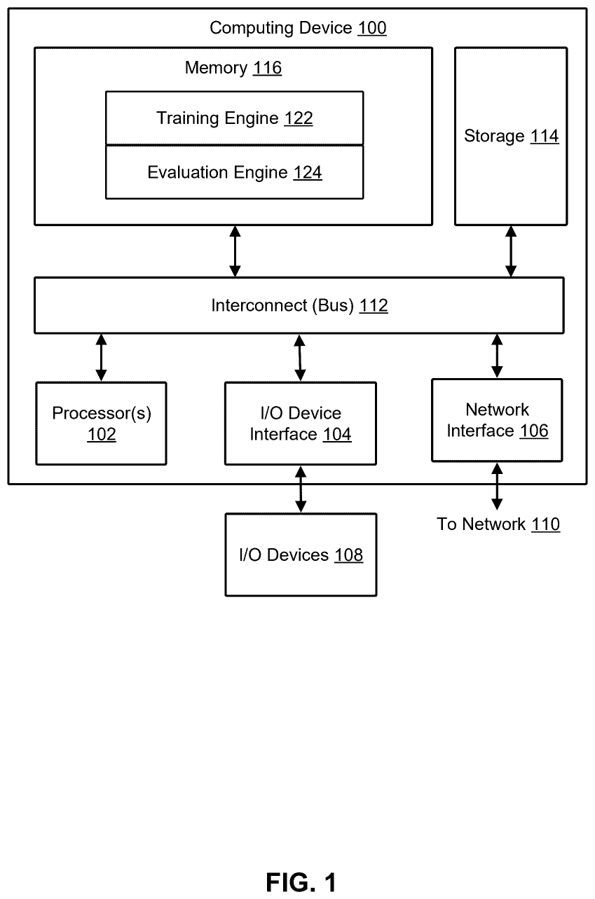

FIG. 1 illustrates a computing device 100 configured to implement one or more aspects of various embodiments. In one embodiment, computing device 100 includes a desktop computer, a laptop computer, a smart phone, a personal digital assistant (PDA), tablet computer, or any other type of computing device configured to receive input, process data, and optionally display images, and is suitable for practicing one or more embodiments. Computing device 100 is configured to run a training engine 122 and an evaluation engine 124 that reside in a memory 116.

It is noted that the computing device described herein is illustrative and that any other technically feasible configurations fall within the scope of the present disclosure. For example, multiple instances of training engine 122 and evaluation engine 124 could execute on a set of nodes in a distributed and/or cloud computing system to implement the functionality of computing device 100. In another example, training engine 122 and/or evaluation engine 124 could execute on various sets of hardware, types of devices, or environments to adapt training engine 122 and/or evaluation engine 124 to different use cases or applications. In a third example, training engine 122 and evaluation engine 124 could execute on different computing devices and/or different sets of computing devices.

In one embodiment, computing device 100 includes, without limitation, an interconnect (bus) 112 that connects one or more processors 102, an input/output (I/O) device interface 104 coupled to one or more input/output (I/O) devices 108, memory 116, a storage 114, and a network interface 106. Processor(s) 102 may be any suitable processor implemented as a central processing unit (CPU), a graphics processing unit (GPU), an application-specific integrated circuit (ASIC), a field programmable gate array (FPGA), an artificial intelligence (AI) accelerator, any other type of processing unit, or a combination of different processing units, such as a CPU configured to operate in conjunction with a GPU. In general, processor(s) 102 may be any technically feasible hardware unit capable of processing data and/or executing software applications. Further, in the context of this disclosure, the computing elements shown in computing device 100 may correspond to a physical computing system (e.g., a system in a data center) or may be a virtual computing instance executing within a computing cloud.

I/O devices 108 include devices capable of providing input, such as a keyboard, a mouse, a touch-sensitive screen, and so forth, as well as devices capable of providing output, such as a display device. Additionally, I/O devices 108 may include devices capable of both receiving input and providing output, such as a touchscreen, a universal serial bus (USB) port, and so forth. I/O devices 108 may be configured to receive various types of input from an end-user (e.g., a designer) of computing device 100, and to also provide various types of output to the end-user of computing device 100, such as displayed digital images or digital videos or text. In some embodiments, one or more of I/O devices 108 are configured to couple computing device 100 to a network 110.

Network 110 is any technically feasible type of communications network that allows data to be exchanged between computing device 100 and external entities or devices, such as a web server or another networked computing device. For example, network 110 may include a wide area network (WAN), a local area network (LAN), a wireless (WiFi) network, and/or the Internet, among others.

Storage 114 includes non-volatile storage for applications and data, and may include fixed or removable disk drives, flash memory devices, and CD-ROM, DVD-ROM, Blu-Ray, HD-DVD, or other magnetic, optical, or solid state storage devices. Training engine 122 and evaluation engine 124 may be stored in storage 114 and loaded into memory 116 when executed.

Memory 116 includes a random access memory (RAM) module, a flash memory unit, or any other type of memory unit or combination thereof. Processor(s) 102, I/O device interface 104, and network interface 106 are configured to read data from and write data to memory 116. Memory 116 includes various software programs that can be executed by processor(s) 102 and application data associated with said software programs, including training engine 122 and evaluation engine 124.

In some embodiments, training engine 122 trains one or more machine learning models to perform human-centric evaluation of an architectural space. In human-centric evaluation, one or more machine learning models generate scores associated with a 2D input view based on one or more human-centric evaluation criteria. Evaluation engine 124 executes machine learning model(s) to generate one or more scores associated with a 2D input view.

More specifically, training engine 122 and evaluation engine 124 are configured to train and execute one or more machine learning models that perform human-centric evaluation of an architectural space based on a 2D input view of the architectural space. The 2D input view may be a photograph, an architectural rendering of the space, or a 2D still image representing a single frame from a 3D video walkthrough of one or more architectural spaces.

### Human-Centric Evaluation

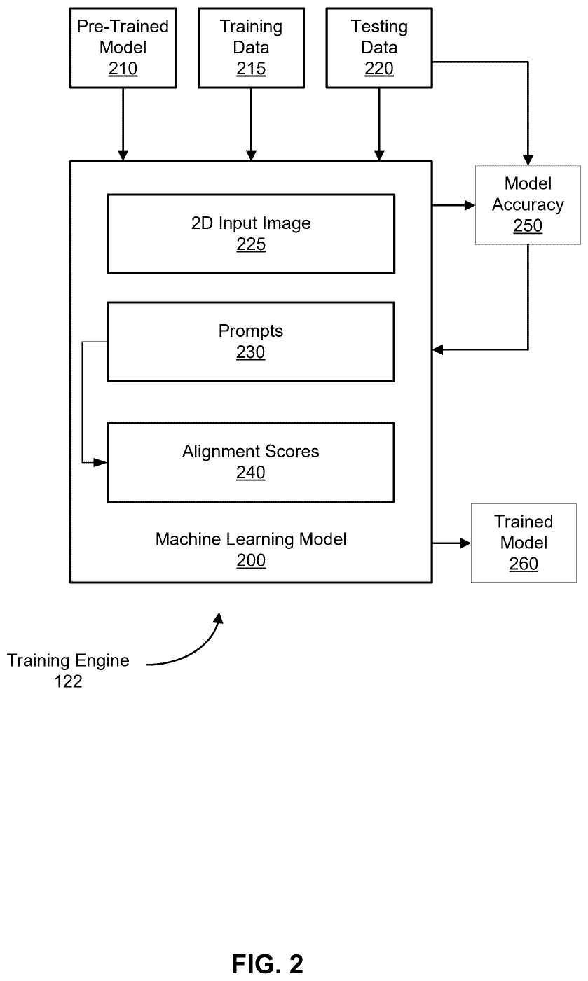

FIG. 2 is a more detailed illustration of training engine 122 of FIG. 1, according to some embodiments. Training engine 122 generates a trained model 260 that generates alignment scores for a 2D input image based on one or more human-centric evaluation criteria. As shown, training engine 122 includes a machine learning model 200, pre-trained model 210, training data 215, testing data 220, 2D input image 225, prompts 230, alignment scores 240, and model accuracy 250. Training engine 122 trains the machine learning model 200 such that scores generated by machine learning model 200 accurately reflect labels associated with testing data 220 to within a predetermined accuracy threshold. After training, training engine 122 generates trained model 260.

Pre-trained model 210 includes a machine learning model that has previously been trained on a labeled training data set of text-image pairs. In various embodiments, pre-trained model 210 is trained on a large data set including tens of millions or hundreds of millions of text-image pairs. For a given textual input and 2D input image, pre-trained model 210 generates an alignment score associated with the textual input and the 2D input image. The alignment score represents a quantitative indication of how accurately the textual input describes the content of the 2D input image. In various embodiments, the generated alignment score may range from 0-1, with scores closer to one indicating a greater degree of alignment between the textual input and the 2D input image, and scores closer to zero representing a lesser degree of alignment between the textual input and the 2D input image. Before training machine learning model 200, training engine 122 assigns the trained parameter values of pre-trained model 210 to machine learning model 200 such that the initial configuration of machine learning model 200 is the same as pre-trained model 210.

Training data 215 and testing data 220 each include a plurality of text-image pairs. In various embodiments, each text-image pair includes a 2D input image that represents an architectural space. Architectural spaces may include, without limitation, spaces such as an office, entryway, meeting space, dining facility, or passageway. For each text-image pair, the 2D input image may include, without limitation, a photograph of an architectural space, a 2D rendering of an architectural space, or a 2D still image representing a single frame of a 3D video walkthrough of one or more architectural spaces. A 2D input image may represent a particular view of an architectural space, the view defined by a specified location of a real or virtual camera, a specified orientation for the real or virtual camera, and a specified field of view for the real or virtual camera.

In various embodiments, each text-image pair in training data 215 and testing data 220 further includes a textual entry associated with the 2D input image included in the text-image pair. The textual entry may include one or more words or sentence fragments, or a complete sentence. The textual entry associated with each text-image pair describes the 2D input image associated with the text-image pair. A textual entry may include one or more human-centric evaluation criteria or properties describing an associated 2D input image. In various embodiments, a textual entry may include the descriptive terms “social,” “isolating,” “tranquil,” “distracting,” “inspirational,” or “boring.” In various embodiments, related pairs of human-centric evaluation criteria may represent opposing endpoint values of a human-centric dimension. For example, the related pair of descriptive terms “social” and “isolating” may represent opposing endpoint values of a human-centric dimension, as may the related terms “tranquil” and “distracting” or “inspirational” and “boring.” In various embodiments, training data 215 and/or testing data may include more than one instance of a particular 2D input image, with each instance of the 2D input image having a different associated textual entry including a single descriptive term. For example, training data 215 may include two instances of a particular 2D image of an office space, with one instance having an associated textual entry including the phrase “This is a social space” and a second instance of the 2D image having an associated textual entry including the phrase “This is an inspirational space.”

Testing data 220 includes image-text pairs that are not included in training data 215 and were not previously used to train pre-trained model 210. Training engine 122 trains machine learning model 200 based on training data 215 and testing data 220, as described below. Training engine 122 further determines an accuracy for machine learning model 200 based on the testing data 220 as described below.

As discussed above, training engine 122 assigns the parameter values of pre-trained model 210 to machine learning model 200, such that the initial configuration of machine learning model 200 is the same as pre-trained model 210. Training engine 122 retrieves a 2D input image 225 from testing data 220 for inclusion as input to machine learning model 200. Training engine 122 further generates one or more prompts 230 for inclusion as input to machine learning model 200. In various embodiments, training engine 122 may generate a prompt for each of one or more human-centric descriptive textual entries included in testing data 220. For example, training engine 122 may generate a prompt stating “This is a social space” or “This is an inspirational space.” Training engine 122 transmits the generated prompt 230 and 2D input image 225 to machine learning model 200.

Machine learning model 200 generates an alignment score 240 based on prompt 230 and 2D input image 225. As discussed above, in various embodiments, generated alignment score 240 may have a value from 0 to 1, with a score closer to one indicating a greater degree of alignment between prompt 230 and 2D input image 225, and a score closer to zero representing a lesser degree of alignment between prompt 230 and the 2D input image.

Training engine 122 generates model accuracy 250 based on testing data 220, prompt 230, and alignment score 240. In various embodiments, for a text-image pair included in testing data 220, training engine 122 calculates an alignment score 240 for both the descriptive term included in the text-image pair and the opposing descriptive term on an associated human-centric dimension. For example, if a text-image pair includes the textual entry “social,” training engine 122 calculates alignment scores 240 using prompts 230 for both the descriptive term “social” and the opposing descriptive term “isolating.” If the alignment score 240 for the descriptive term included in the text-image pair is higher than the alignment score for the opposing descriptive term, then training engine 122 determines that machine learning model 200 has accurately predicted the alignment between 2D input image 225 and prompt 230. If the alignment score 240 for the descriptive term included in the text-image pair is lower than the alignment score for the opposing descriptive term, then training engine 122 determines that machine learning model 200 has not accurately predicted the alignment between 2D input image 225 and prompt 230.

For each input image 225 included in testing data 220, training engine 122 repeats the above scoring process for each generated prompt 230 and records whether or not machine learning model 200 accurately predicted the alignment between prompt 230 and 2D input image 225. In various embodiments, each generated prompt 230 includes one of the human-centric descriptive terms “social,” “isolating,” “tranquil,” “distracting,” “inspirational,” and “boring.”

Training engine 122 analyzes each of the text-image pairs included in testing data 220 and generates a set of prompts 230 and associated alignment scores 240. Training engine 122 generates model accuracy 250 based on a percentage of prompts 230 for which machine learning model 200 accurately predicted the alignment between the prompt 230 and associated 2D input image 225 from testing data 220.

If training engine 122 determines that model accuracy 250 is equal to or greater than a predetermined model accuracy threshold percentage, training engine 122 transmits the trained parameters of machine learning model 200 to trained model 260.

If training engine 122 determines that model accuracy 250 is less than the predetermined model accuracy threshold percentage, training engine 122 trains machine learning model 200 by transmitting a predetermined quantity of text-image pairs from training data 215 to machine learning model 200 and iteratively adjusting parameters of machine learning model 200 based on 2D input images 225 from training data 215, prompts 230, and generated alignment scores 240 from machine learning model 200. After iteratively adjusting the parameters of machine learning model 200 based on the predetermined quantity of text-image pairs from training data 215, training engine 122 again processes testing data 220 via machine learning model 200. Training engine 122 re-evaluates model accuracy 250 as described above. If training engine 122 determines that model accuracy 250 is equal to or greater than the predetermined model accuracy threshold percentage, training engine 122 transmits the trained parameters of machine learning model 200 to trained model 260. If training engine 122 determines that model accuracy 250 is less than the predetermined model accuracy threshold percentage, training engine 122 continues training machine learning model on additional text-image pairs from training data 215 as described above.

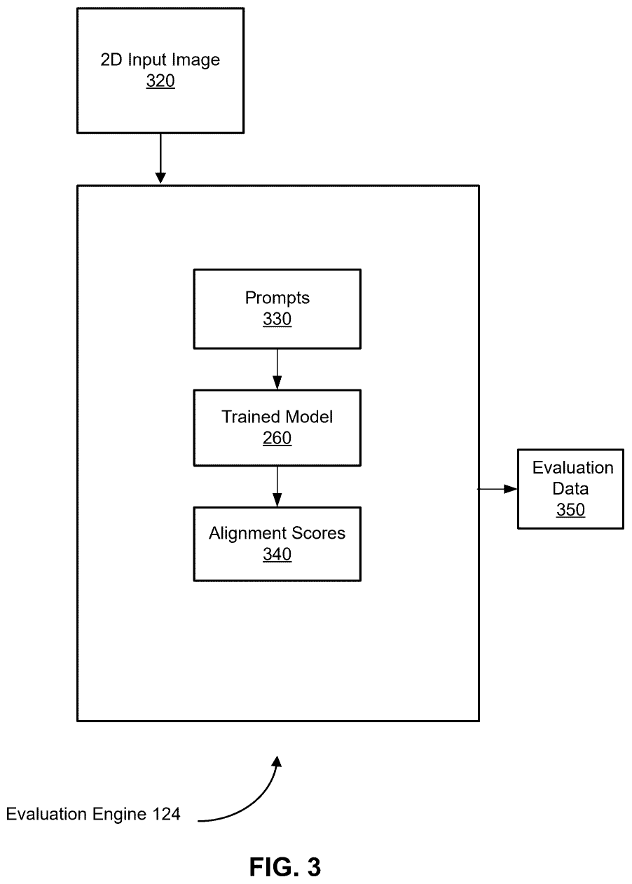

FIG. 3 is a more detailed illustration of evaluation engine 124 of FIG. 1, according to some embodiments. Evaluation engine 124 generates a plurality of alignment scores based on a 2D input image and a plurality of textual prompts. As shown, training engine 122 includes trained model 260, prompts 330, alignment scores 340, and evaluation data 350. Evaluation engine 124 receives 2D input image 320 and generates evaluation data 350.

Evaluation engine 124 receives a 2D input image 320 from a human user or an upstream software application. In various embodiments, 2D input image 320 may be a photograph of an architectural space, a 2D rendering of an architectural space, or a 2D still image representing a single frame included in a 3D video walkthrough of one or more architectural spaces.

Evaluation engine 124 generates one or more prompts 330. Each of the one or more prompts 330 includes one of a plurality of predetermined human-centric descriptive terms. In various embodiments, each generated prompt 330 includes one of the human-centric descriptive terms “social,” “isolating,” “tranquil,” “distracting,” “inspirational,” and “boring.” For example, a prompt 330 may include the statement “this is an inspirational space” or “this is a social space.”

For each prompt 330, evaluation engine 124 transmits the prompt 330 and the 2D input image 320 to trained model 260. Trained model 260 calculates an alignment score 340 associated with the prompt 330 and 2D input image 320. The alignment score 340 represents a degree of alignment between 2D input image 320 and the descriptive term included in the associated prompt 330. In various embodiments, the generated alignment score 340 may have a value from 0 to 1, with a score closer to one indicating a greater degree of alignment between prompt 330 and 2D input image 320, and a score closer to zero representing a lesser degree of alignment between prompt 330 and 2D input image 320.

Evaluation engine 124 transmits 2D input image 320 and the alignment scores 340 corresponding to the one or more prompts 330 to evaluation data 350 for presentation to a user. Evaluation engine 124 may further record 2D input image 320 and the associated alignment scores 340, e.g., in storage 114.

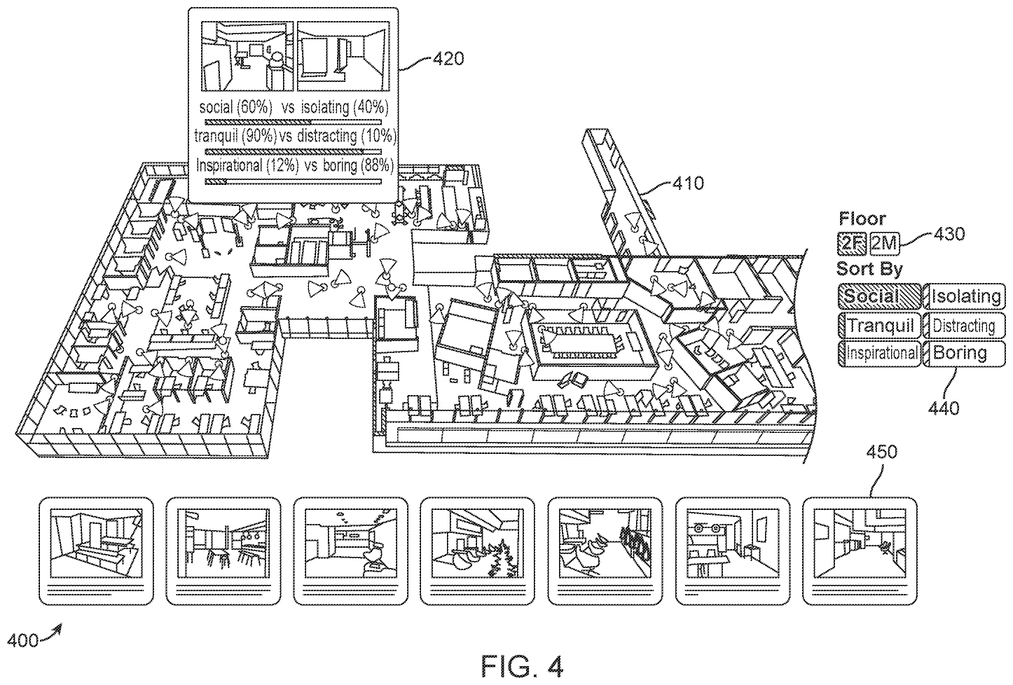

FIG. 4 illustrates an example evaluation display, according to various embodiments. Evaluation engine 124 may generate evaluation display 400 based on data included in evaluation data 350 and/or stored in storage 114 as discussed above in reference to FIG. 3. Evaluation display 400 may be displayed on a graphical user interface (GUI).

Display element 410 of evaluation display 400 represents a floor plan image of a portion of a building. Display element 410 includes one or more colored and/or shaded circles representing architectural spaces that have been evaluated by evaluation engine 124. Each circle defines a location from which a 2D image of an architectural space was captured or rendered. Each circle includes an associated arc that indicates a viewing direction for a real or virtual camera used to capture the 2D image of the architectural space.

Display element 420 represents a detail view of one or more 2D images and one or more alignment scores for an architectural space associated with a user-selected circle in display element 410. In various embodiments, display element 420 may include alignment scores for pairs of human-centric evaluation criteria that represent opposing endpoints of a human-centric dimension. For example, display element 420 as shown includes the related pair of human-centric evaluation criteria “social” and “isolating” with respective alignment scores of 60% and 40% and a bar graph indicating that the selected architectural space is more “social” (60%) than “isolating” (40%). In various embodiments, the displayed alignment scores may be a percentage representation of generated alignment scores that vary from 0 to 1 as described above in reference to FIG. 3.

Display element 430 represents a display of available and user-selectable portions of a building for display in evaluation display 400. As shown, portion “2F” has been selected and corresponds to the portion of the building shown in display element 410.

Display element 440 represents user-selectable depictions of a plurality of human-centric evaluation criteria. As shown, a user has selected the human-centric evaluation criteria “Social.” In various embodiments, selecting a particular human-centric evaluation criteria in display element 440 may automatically adjust the coloring and/or shading of one or more circles depicted in display element 410. For example, if the human user selects “Social” in display element 440, the circles depicted in display element 410 corresponding to architectural spaces having relatively higher social alignment scores may be displayed in shades of green, while architectural spaces having relatively lower social alignment scores may be displayed in shades of red. In various embodiments, specific colors or levels of shading for circles in display element 410 may be associated with particular value ranges of alignment scores for the human-centric evaluation criteria selected in display element 440.

Display element 450 displays a plurality of 2D images and alignment scores corresponding to architectural spaces having the highest alignment scores for the human-centric evaluation criteria selected in display element 440. In various embodiments, display element 450 may display a single representative 2D image for each of the corresponding architectural spaces and may display the corresponding alignment scores as percentage values, bar graphs, or as any other technically feasible depiction.

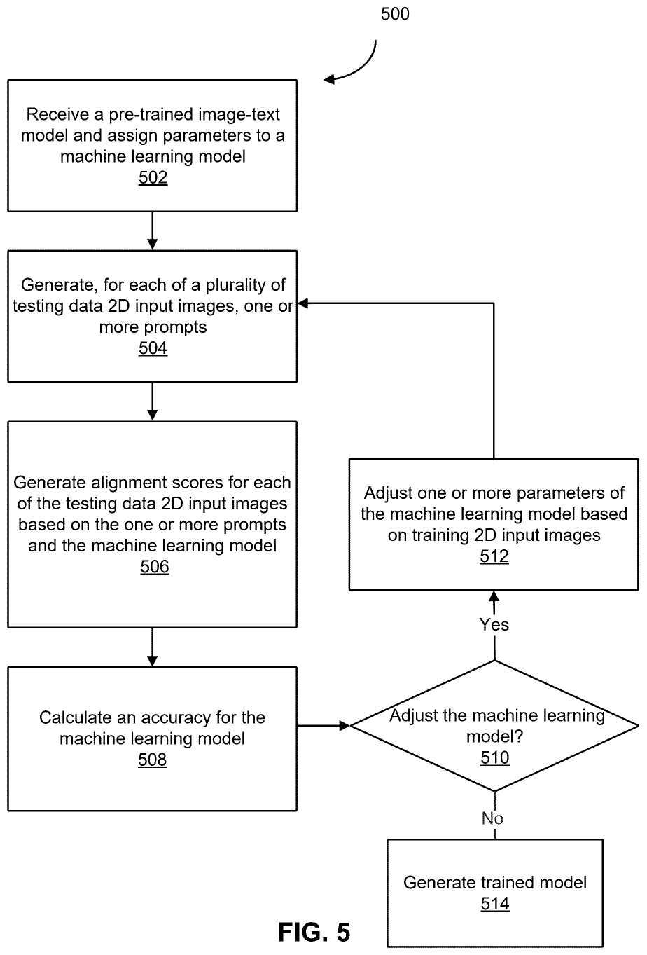

FIG. 5 is a flow diagram of method steps for training a machine learning model to generate alignment scores for a 2D input image based on one or more human-centric evaluation criteria, according to various embodiments. Although the method steps are described in conjunction with the systems of FIGS. 1-3, persons skilled in the art will understand that any system configured to perform the method steps in any order falls within the scope of the present disclosure.

As shown, in operation 502 of method 500, training engine 122 receives a pre-trained image-text model. Training engine 122 assigns parameters of the pre-trained image-text model to a machine learning model such that the initial configuration of the machine learning model is the same as pre-trained image-text model.

In operation 504, training engine 122 generates one or more prompts for a 2D input image included in a testing data set of image-text pairs. Each of the generated prompts includes one of a plurality of human-centric evaluation criteria as a word, a sentence fragment, or a complete sentence. For example, a prompt may include the phrase “this is a social space.” In various embodiments, the plurality of human-centric evaluation criteria may include “social,” “isolating,” “tranquil,” “distracting,” “inspirational,” or “boring.”

In operation 506, training engine 122 generates, via the machine learning model, alignment scores for each of the prompts based on the prompt and the associated 2D input image. In various embodiments, each of the generated alignment scores may have a value from 0 to 1, with a score closer to one indicating a greater degree of alignment between the prompt and the 2D input image, and a score closer to zero representing a lesser degree of alignment between the prompt and the 2D input image. Training engine 122 may repeat operations 504 and 506 until training engine 122 has generated alignment scores associated with each prompt for all 2D images included in the testing data set.

In operation 508, training engine 122 calculates an accuracy for the machine learning model. In various embodiments, the accuracy may include a percentage representation of the portion of generated alignment scores that correctly indicated an alignment between a 2D input image and a prompt containing a human-centric criteria associated with the 2D image in the testing data set.

In operation 510, training engine 122 determines whether to adjust the machine learning model. If the calculated testing data set accuracy from operation 508 meets or exceeds a predetermined threshold, training engine 122 does not adjust the machine learning model and proceeds to generate a trained model in operation 514. If the calculated testing data set accuracy from operation 508 does not meet or exceed the predetermined threshold, training engine 122 proceeds to operation 512.

In operation 512, training engine 122 iteratively adjusts one or more parameters of the machine learning model. During each iteration, training engine 122 generates prompts for a 2D input image included in a training data set of image-text pairs and generates alignment scores associated with each of the prompt and the 2D input image. Training engine 122 further adjusts one or more parameters of the machine learning model based on the generated alignment scores and ground truth image-text data included in the training data set. In various embodiments, training engine 122 may continue this iterative training process for a predetermined number of image-text pairs in the training data set. After training the machine learning model, training engine 122 returns to operation 504 and processes the image-text pairs in the testing data set, recalculates the accuracy for the machine learning model, and evaluates whether further adjustments to the machine learning model are needed.

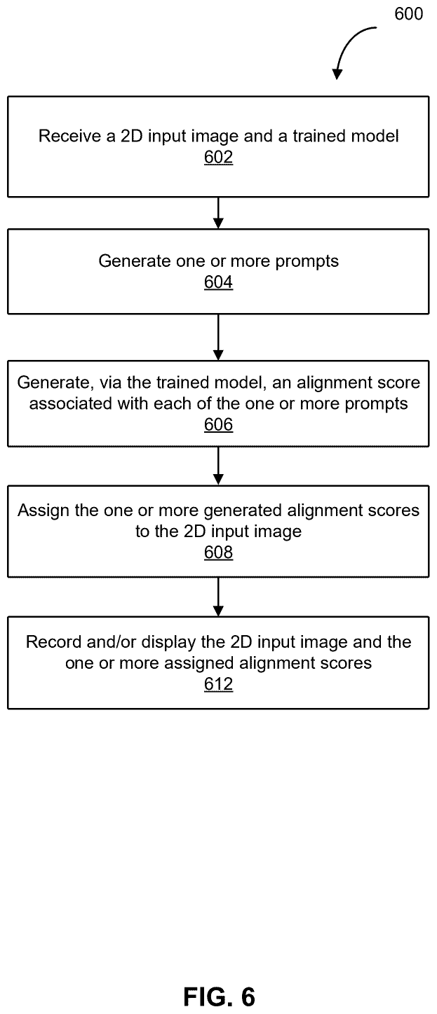

FIG. 6 is a flow diagram of method steps for performing human-centric evaluation of an architectural space, according to various embodiments. Although the method steps are described in conjunction with the systems of FIGS. 1-3, persons skilled in the art will understand that any system configured to perform the method steps in any order falls within the scope of the present disclosure.

As shown, in operation 602 of method 600, evaluation engine 124 receives a 2D input image of an architectural space from a user or upstream software application. Evaluation engine 124 further receives a trained model from training engine 122. In various embodiments, the 2D input image may be a photograph, a 2D rendering, or a 2D still image representing a single frame of a 3D video walkthrough of one or more architectural spaces.

In operation 604, evaluation engine 124 generates one or more prompts for the 2D input image. Each of the generated prompts includes one of a plurality of human-centric evaluation criteria as a word, a sentence fragment, or a complete sentence. For example, a prompt may include the phrase “this is a social space.” In various embodiments, the plurality of human-centric evaluation criteria may include “social,” “isolating,” “tranquil,” “distracting,” “inspirational,” or “boring.”

In operation 606, evaluation engine 124 generates, via the trained model, alignment scores for each of the prompts based on the prompt and the associated 2D input image. In various embodiments, each of the generated alignment scores may have a value from 0 to 1, with a score closer to one indicating a greater degree of alignment between the prompt and the 2D input image, and a score closer to zero representing a lesser degree of alignment between the prompt and the 2D input image.

In operation 608, evaluation engine 124 associates each of the human-centric evaluation criteria and the associated alignment score with the 2D input image. In operation 612, evaluation engine 124 records the 2D input image and the associated human-centric evaluation criteria and alignment scores, e.g., in storage 114. Evaluation engine 124 may further generate a display of one or more architectural spaces, associated human-centric evaluation criteria, and alignment scores for presentation to a human user.

In sum, the disclosed techniques train and execute a machine learning model to evaluate a 2D input image of an architectural space and generate one or more corresponding alignment scores for the 2D input image based on a plurality of human-centric evaluation criteria. The 2D input image may be a photograph of an architectural space, a 2D rendering of the architectural space, or a 2D still image representing a single frame from a 3D video walkthrough of one or more architectural spaces.

The machine learning model initially receives parameter values from a pre-trained image-text machine learning model. The machine learning model receives as input a 2D input image of an architectural space and a prompt. The prompt includes a human-centric descriptive term such as “boring,” “inspirational,” “social,” or “tranquil.” The machine learning model generates an alignment score that indicates how closely the 2D input image aligns with the human-centric descriptive term included in the prompt. The generated alignment score may have a value from 0 to 1, with a score closer to one indicating a greater degree of alignment between the prompt and the 2D input image, and a score closer to zero representing a lesser degree of alignment between the prompt and the 2D input image.

During training, the machine learning model is evaluated against a testing data set of image-text data pairs. For each data pair in the testing set, the machine learning model generates alignment scores for each of a plurality of prompts. If the generated alignment scores indicate a sufficiently high alignment between the 2D images in the testing data set of image-text data pairs and descriptive terms included in the plurality of prompts, the machine learning model is stored as a trained model. If the generated alignment scores do not indicate a sufficiently high alignment between the 2D images in the testing data set of image-text data pairs and descriptive terms included in the plurality of prompts, the machine learning model is iteratively trained on text-image pairs included in a training data test set until the generated alignment scores indicate a sufficiently high alignment between the 2D images in the testing data set of image-text data pairs and descriptive terms included in the plurality of prompts.

At evaluation time, an evaluation engine receives a 2D input image from a user or upstream software application. The evaluation engine generates a plurality of prompts, wherein each prompt includes a human-centric descriptive term such as “boring,” “inspirational,” “social,” or “tranquil.” The evaluation engine transmits a generated prompt and the 2D input image to the trained model, and the trained model generates an alignment score that indicates how closely the 2D input image aligns with the human-centric descriptive term included in the prompt. The generated alignment score may have a value from 0 to 1, with a score closer to one indicating a greater degree of alignment between the prompt and the 2D input image, and a score closer to zero representing a lesser degree of alignment between the prompt and the 2D input image. The evaluation engine generates and records alignment scores associated with each generated prompt and transmits the 2D input image and associated alignment scores to a display for presentation to a user.

One technical advantage of the disclosed technique relative to the prior art is that the disclosed techniques provide consistent, quantifiable, repeatable evaluations of architectural spaces based on human-centric evaluation criteria. The disclosed techniques refine a pre-trained model by iteratively training the model on a relatively smaller quantity of image-text pairs representing human evaluations of architectural spaces. The disclosed techniques may be applied to two-dimensional (2D) photographs of architectural spaces, 2D renderings of architectural spaces, or 2D still images representing individual frames from a 3D video walkthrough of one or more architectural spaces. These technical advantages provide one or more technological improvements over prior art approaches.

1. In some embodiments, a computer-implemented method for evaluating an architectural space, the computer-implemented method comprises generating a textual prompt, wherein the textual prompt includes a human-centric evaluation criterion, generating, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion, assigning the human-centric evaluation criterion and the alignment score to the 2D input image, and displaying, via a graphical user interface, one or more of the 2D input image, the human-centric evaluation criterion, and the alignment score.

2. The computer-implemented method of clause 1, wherein the human-centric evaluation criterion includes one of the terms “social,” “isolating,” “tranquil,” “distracting,” “inspirational,” or “boring.”

3. The computer-implemented method of clauses 1 or 2, wherein the 2D input image is one of a photograph of an architectural space, a 2D rendering of an architectural space, or a still image representing a single frame included in a video recording of an architectural space.

4. The computer-implemented method of any of clauses 1-3, further comprising initializing, based on a pre-trained model, a plurality of learnable parameters included in the machine learning model, iteratively adjusting one or more of the plurality of learnable parameters based on a first plurality of alignment scores generated for a first plurality of image-text pairs included in a training data set, calculating an accuracy associated with the machine learning model based on a second plurality of alignment scores generated for a second plurality of image-text pairs included in a testing data set, and continuing or terminating the iterative adjustment of the one or more of the plurality of learnable parameters based on the calculated accuracy.

5. The computer-implemented method of any of clauses 1-4, wherein each image-text pair included in the first and second pluralities of image-text pairs includes an image representing an architectural space and a ground truth human-centric evaluation criterion associated with the image.

6. The computer-implemented method of any of clauses 1-5, further comprising displaying, via the graphical user interface, simultaneous visual representations of a plurality of architectural spaces and a plurality of alignment scores associated with the plurality of architectural spaces.

7. The computer-implemented method of any of clauses 1-6, wherein the simultaneous visual representations of the plurality of architectural spaces are arranged on the graphical user interface based on the plurality of alignment scores associated with the plurality of architectural spaces.

8. In some embodiments, one or more non-transitory computer-readable media store instructions that, when executed by one or more processors, cause the one or more processors to perform the steps of generating a textual prompt, wherein the textual prompt includes a human-centric evaluation criterion, generating, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion, assigning the human-centric evaluation criterion and the alignment score to the 2D input image, and displaying, via a graphical user interface, one or more of the 2D input image, the human-centric evaluation criterion, and the alignment score.

9. The one or more non-transitory computer-readable media of clause 8, wherein the human-centric evaluation criterion includes one of the terms “social,” “isolating,” “tranquil,” “distracting,” “inspirational,” or “boring.”

10. The one or more non-transitory computer-readable media of clauses 8 or 9, wherein the 2D input image is one of a photograph of an architectural space, a 2D rendering of an architectural space, or a still image representing a single frame included in a video recording of an architectural space.

11. The one or more non-transitory computer-readable media of any of clauses 8-10, wherein the instructions further cause the one or more processors to perform the steps of initializing, based on a pre-trained model, a plurality of learnable parameters included in the machine learning model, iteratively adjusting one or more of the plurality of learnable parameters based on a first plurality of alignment scores generated for a first plurality of image-text pairs included in a training data set, calculating an accuracy associated with the machine learning model based on a second plurality of alignment scores generated for a second plurality of image-text pairs included in a testing data set, and continuing or terminating the iterative adjustment of the one or more of the plurality of learnable parameters based on the calculated accuracy.

12. The one or more non-transitory computer-readable media of any of clauses 8-11, wherein each image-text pair included in the first and second pluralities of image-text pairs includes an image representing an architectural space and a ground truth human-centric evaluation criterion associated with the image.

13. The one or more non-transitory computer-readable media of any of clauses 8-12, wherein the instructions further cause the one or more processors to perform the steps of displaying, via the graphical user interface, simultaneous visual representations of a plurality of architectural spaces and a plurality of alignment scores associated with the plurality of architectural spaces.

14. The one or more non-transitory computer-readable media of any of clauses 8-13, wherein the simultaneous visual representations of the plurality of architectural spaces are arranged on the graphical user interface based on the plurality of alignment scores associated with the plurality of architectural spaces.

15. In some embodiments, a system comprises one or more memories storing instructions, and one or more processors for executing the instructions to generate a textual prompt, wherein the textual prompt includes a human-centric evaluation criterion, generate, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion, assign the human-centric evaluation criterion and the alignment score to the 2D input image, and display, via a graphical user interface, one or more of the 2D input image, the human-centric evaluation criterion, and the alignment score.

16. The system of clause 15, wherein the human-centric evaluation criterion includes one of the terms “social,” “isolating,” “tranquil”, “distracting,” “inspirational,” or “boring.”

17. The system of clauses 15 or 16, wherein the 2D input image is one of a photograph of an architectural space, a 2D rendering of an architectural space, or a still image representing a single frame included in a video recording of an architectural space.

18. The system of any of clauses 15-17, wherein the instructions further cause the one or more processors to initialize, based on a pre-trained model, a plurality of learnable parameters included in the machine learning model, iteratively adjust one or more of the plurality of learnable parameters based on a first plurality of alignment scores generated for a first plurality of image-text pairs included in a training data set, calculate an accuracy associated with the machine learning model based on a second plurality of alignment scores generated for a second plurality of image-text pairs included in a testing data set, and continue or terminate the iterative adjustment of the one or more of the plurality of learnable parameters based on the calculated accuracy.

19. The system of any of clauses 15-18, wherein each image-text pair included in the first and second pluralities of image-text pairs includes an image representing an architectural space and a ground truth human-centric evaluation criterion associated with the image.

20. The system of any of clauses 15-19, wherein the instructions further cause the one or more processors to display, via the graphical user interface, simultaneous visual representations of a plurality of architectural spaces and a plurality of alignment scores associated with the plurality of architectural spaces.

Any and all combinations of any of the claim elements recited in any of the claims and/or any elements described in this application, in any fashion, fall within the contemplated scope of the present invention and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for evaluating an architectural space, the computer-implemented method comprising:
generating a textual prompt, wherein the textual prompt includes a human-centric evaluation criterion;
generating, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion;
assigning the human-centric evaluation criterion and the alignment score to the 2D input image; and
displaying, via a graphical user interface, one or more of the 2D input image, the human-centric evaluation criterion, and the alignment score.

2. The computer-implemented method of claim 1, wherein the human-centric evaluation criterion includes one of the terms “social,” “isolating,” “tranquil,” “distracting,” “inspirational,” or “boring.”

3. The computer-implemented method of claim 1, wherein the 2D input image is one of a photograph of an architectural space, a 2D rendering of an architectural space, or a still image representing a single frame included in a video recording of an architectural space.

4. The computer-implemented method of claim 1, further comprising:
initializing, based on a pre-trained model, a plurality of learnable parameters included in the machine learning model;
iteratively adjusting one or more of the plurality of learnable parameters based on a first plurality of alignment scores generated for a first plurality of image-text pairs included in a training data set;
calculating an accuracy associated with the machine learning model based on a second plurality of alignment scores generated for a second plurality of image-text pairs included in a testing data set; and
continuing or terminating the iterative adjustment of the one or more of the plurality of learnable parameters based on the calculated accuracy.

5. The computer-implemented method of claim 4, wherein each image-text pair included in the first and second pluralities of image-text pairs includes an image representing an architectural space and a ground truth human-centric evaluation criterion associated with the image.

6. The computer-implemented method of claim 1, further comprising displaying, via the graphical user interface, simultaneous visual representations of a plurality of architectural spaces and a plurality of alignment scores associated with the plurality of architectural spaces.

7. The computer-implemented method of claim 6, wherein the simultaneous visual representations of the plurality of architectural spaces are arranged on the graphical user interface based on the plurality of alignment scores associated with the plurality of architectural spaces.

8. One or more non-transitory computer-readable media storing instructions that, when executed by one or more processors, cause the one or more processors to perform the steps of:
generating a textual prompt, wherein the textual prompt includes a human-centric evaluation criterion;
generating, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion;
assigning the human-centric evaluation criterion and the alignment score to the 2D input image; and
displaying, via a graphical user interface, one or more of the 2D input image, the human-centric evaluation criterion, and the alignment score.

9. The one or more non-transitory computer-readable media of claim 8, wherein the human-centric evaluation criterion includes one of the terms “social,” “isolating,” “tranquil,” “distracting,” “inspirational,” or “boring.”

10. The one or more non-transitory computer-readable media of claim 8, wherein the 2D input image is one of a photograph of an architectural space, a 2D rendering of an architectural space, or a still image representing a single frame included in a video recording of an architectural space.

11. The one or more non-transitory computer-readable media of claim 8, wherein the instructions further cause the one or more processors to perform the steps of:
initializing, based on a pre-trained model, a plurality of learnable parameters included in the machine learning model;
iteratively adjusting one or more of the plurality of learnable parameters based on a first plurality of alignment scores generated for a first plurality of image-text pairs included in a training data set;
calculating an accuracy associated with the machine learning model based on a second plurality of alignment scores generated for a second plurality of image-text pairs included in a testing data set; and
continuing or terminating the iterative adjustment of the one or more of the plurality of learnable parameters based on the calculated accuracy.

12. The one or more non-transitory computer-readable media of claim 11, wherein each image-text pair included in the first and second pluralities of image-text pairs includes an image representing an architectural space and a ground truth human-centric evaluation criterion associated with the image.

13. The one or more non-transitory computer-readable media of claim 8, wherein the instructions further cause the one or more processors to perform the steps of:
displaying, via the graphical user interface, simultaneous visual representations of a plurality of architectural spaces and a plurality of alignment scores associated with the plurality of architectural spaces.

14. The one or more non-transitory computer-readable media of claim 13, wherein the simultaneous visual representations of the plurality of architectural spaces are arranged on the graphical user interface based on the plurality of alignment scores associated with the plurality of architectural spaces.

15. A system comprising:
one or more memories storing instructions; and
one or more processors for executing the instructions to:
generate a textual prompt, wherein the textual prompt includes a human-centric evaluation criterion;
generate, via a machine learning model, an alignment score based on the textual prompt and a two-dimensional (2D) input image, wherein the 2D input image is a visual representation of an architectural space, and the alignment score is a quantitative measure of how accurately the textual prompt describes the 2D input image based on the human-centric evaluation criterion;
assign the human-centric evaluation criterion and the alignment score to the 2D input image; and
display, via a graphical user interface, one or more of the 2D input image, the human-centric evaluation criterion, and the alignment score.

16. The system of claim 15, wherein the human-centric evaluation criterion includes one of the terms “social,” “isolating,” “tranquil”, “distracting,” “inspirational,” or “boring.”

17. The system of claim 15, wherein the 2D input image is one of a photograph of an architectural space, a 2D rendering of an architectural space, or a still image representing a single frame included in a video recording of an architectural space.

18. The system of claim 15, wherein the instructions further cause the one or more processors to:
initialize, based on a pre-trained model, a plurality of learnable parameters included in the machine learning model;
iteratively adjust one or more of the plurality of learnable parameters based on a first plurality of alignment scores generated for a first plurality of image-text pairs included in a training data set;
calculate an accuracy associated with the machine learning model based on a second plurality of alignment scores generated for a second plurality of image-text pairs included in a testing data set; and
continue or terminate the iterative adjustment of the one or more of the plurality of learnable parameters based on the calculated accuracy.

19. The system of claim 18, wherein each image-text pair included in the first and second pluralities of image-text pairs includes an image representing an architectural space and a ground truth human-centric evaluation criterion associated with the image.

20. The system of claim 15, wherein the instructions further cause the one or more processors to display, via the graphical user interface, simultaneous visual representations of a plurality of architectural spaces and a plurality of alignment scores associated with the plurality of architectural spaces.
